(19) United States
(12) Patent Application Publication
(10) Pub. No.: US 2007/0172965 A1
(43) Pub. Date: Jul. 26, 2007

(54) NON-DESTRUCTIVE TRENCH VOLUME DETERMINATION AND TRENCH CAPACITANCE PROJECTION

(76) Inventors: Kangguo Cheng, Beacon, NY (US); Xi Li, Somers, NY (US)

Correspondence Address: HOFFMAN, WARNICK & D'ALESSANDRO LLC, 75 STATE ST, 14TH FL, ALBANY, NY, 12207, US

(21) Appl. No.: 11/275,663

(22) Filed: Jan. 23, 2006

(51) Int. Cl. H01L 21/66; H01L 21/76

(52) U.S. Cl. 438/14; 438/424; 438/436; 438/16; 257/E21.529

(57) ABSTRACT

Methods of determining trench volume are disclosed. In one embodiment, the method includes providing a semiconductor substrate with at least one trench in a trench area; filling each trench with a filling material; measuring a step height between the trench area and a trench free area; and determining the trench volume based on the step height. The embodiments provide a simple, nondestructive, cost-effective, highly scalable and reliable trench volume measurement. The step height can also be used as part of a method to project trench capacitance where the trench will be used for a trench capacitor.

### BACKGROUND OF THE INVENTION

1. Technical Field

The invention relates generally to dimension measurement, and more particularly, to a non-destructive method for determining the volume of a trench in a semiconductor substrate.

2. Background Art

Measurement of openings and, in particular, trenches in the semiconductor industry is an essential step in manufacturing and development of semiconductor devices. For example, trench parameters such as volume and surface area have significant impacts on trench capacitor characteristics such as capacitance, resistance, and leakage current. Trench capacitors have been widely used in various applications such as dynamic random access memory (DRAM), embedded DRAM, system-on-chips, etc. Therefore, it is desired to measure the trench characteristics to evaluate process integrity and predict device parameters.

Conventional approaches for measuring trenches can be classified into two categories: destructive and nondestructive. In a destructive approach, a wafer including trenches is cleaved and the cross-section of the trenches is imaged by a microscope such as scanning electron microscope (SEM). This approach, however, has several disadvantages. First, wafers cleaved for SEM imaging are destroyed and no longer useful. Second, an SEM analysis may take several hours for sampling preparation and imaging. Third, a destructive approach is not compatible with the automated semiconductor manufacturing process because the wafer has to be manually taken out from the manufacturing line. Fourth, only a couple of trenches are imaged and measured, resulting in the measurement not being accurately representative of all wafers. Finally, the measurement obtained is not applicable to all wafers due to its destructive nature. Therefore, wafer-to-wafer variation cannot be measured and minimized.

The other approach for trench measurement is nondestructive. This approach, however, also has disadvantages. First, sophisticated optical setup is used, resulting in prohibitively high equipment investment. Second, the measurement accuracy relies on revolving the sophisticated optical spectra by advanced software, which is usually proprietary. Third, most types of this approach are dependent on the size of the trench opening. As a result, as semiconductor technology advances to smaller device dimensions, this approach faces severe scaling challenges. Cost associated with equipment and software upgrade for measuring smaller trench size will be prohibitively high even if measurement limits are not achieved. Finally, this approach is only capable of measuring trench depth, and/or trench dimensions at a given depth. That is, the conventional non-destructive approaches cannot directly measure the trench volume, which is one of the most important parameters because it directly correlates to device parameters such as capacitance.

With further regard to trench capacitors, knowing the trench capacitance is one of the most important parameters for trench DRAM, embedded DRAM, application specific integrated circuits (ASICs), and system-on-chip products. In particular, it is advantageous to know the trench capacitance and use that data for process optimization. Unfortunately, trench capacitance cannot be directly measured until wafers reach the end of the process. Because it takes several weeks before a wafer reaches the final test, awaiting final test extends the duration of process development.

Therefore there is a need for a solution to the problems of the related art.

### SUMMARY OF THE INVENTION

Methods of determining trench volume are disclosed. In one embodiment, the method includes providing a semiconductor substrate with at least one trench in a trench area; filling each trench with a filling material; measuring a step height between the trench area and a trench free area; and determining the trench volume based on the step height. The embodiments provide a simple, nondestructive, cost-effective, highly scalable and reliable trench volume measurement. The step height can also be used as part of a method to project trench capacitance where the trench will be used for a trench capacitor.

A first aspect of the invention provides a method of determining trench volume, the method comprising the steps of: providing a semiconductor substrate with at least one trench in a trench area; filling each trench with a filling material; measuring a step height between the trench area and a trench free area; and determining the trench volume based on the step height.

A second aspect of the invention provides a method of determining trench volume, the method comprising the steps of: providing a semiconductor substrate with a plurality of trenches in a trench area; coating the semiconductor substrate with a filling material that fills each trench, the filling material including at least one solute and at least one solvent; removing at least a portion of the solvent in the filling material; measuring a step height between the trench area and a trench free area; and determining the trench volume based on the step height, the determination based on an empirical correlation between the step height and the trench volume.

A third aspect of the invention provides a method of projecting a trench capacitance of a trench capacitor, the method comprising the steps of: providing a semiconductor substrate with a plurality of trenches in a trench area; coating the semiconductor substrate with a resist that fills each trench, the resist including at least one solute and at least one solvent; removing at least a portion of the solvent in the resist by heating the semiconductor substrate; measuring a step height between the trench area and a trench free area using a profilometer; and projecting the capacitance of the trench based on the step height, the determination based on an empirical correlation between the step height and the trench capacitance.

The illustrative aspects of the present invention are designed to solve the problems herein described and/or other problems not discussed.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows an illustrative semiconductor substrate including trenches.

FIG. 2 shows a filling material applied to the semiconductor substrate of FIG. 1 according to one embodiment of the invention.

FIG. 3 shows a flow diagram of one embodiment of a method according to the invention.

FIG. 4 shows a graphical user interface output from one embodiment of a profilometer used with the method of FIG. 3.

FIG. 5 shows a chart illustrating a correlation of step height and trench capacitance.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

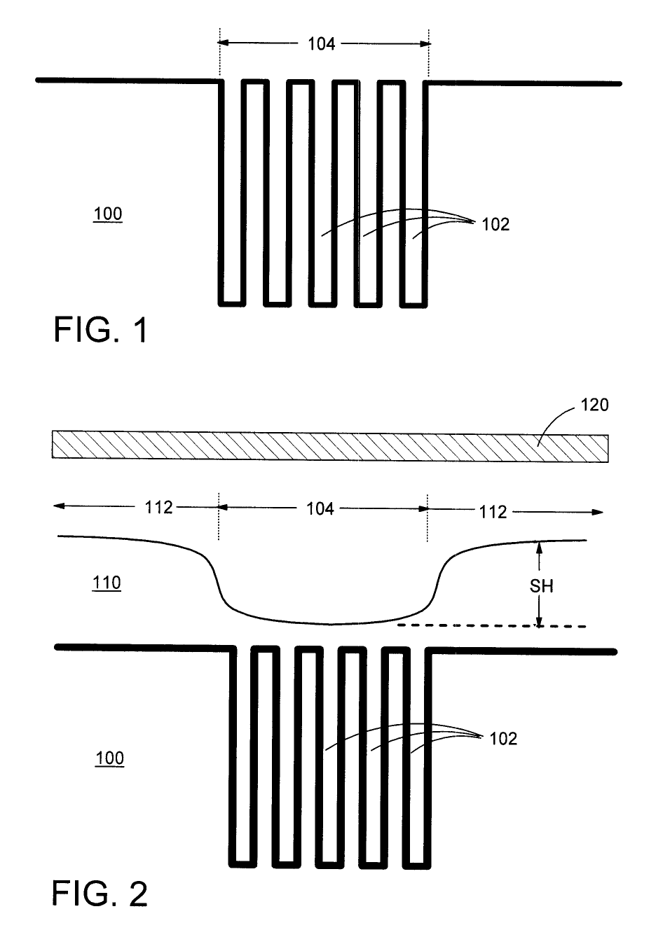

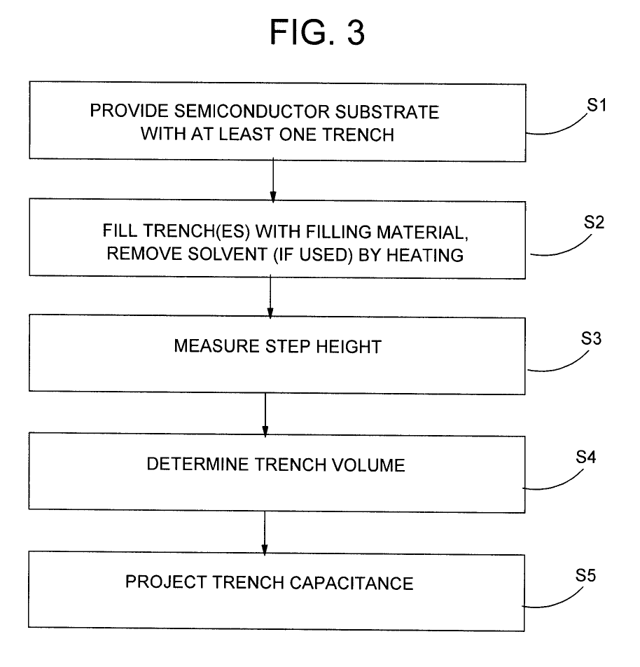

Turning to the drawings, FIGS. 1-3 will now be referenced to describe one embodiment of a method determining trench volume. Referring to FIG. 1, along with the flow diagram of FIG. 3, a first step S1 includes providing a semiconductor substrate 100 including at least one trench 102 in a trench area 104. In most cases, a plurality of trenches 102 is provided. Trench(es) 102 may be formed in any now known or later developed fashion, e.g., standard patterning and etching processes. Semiconductor substrate 100 may include other structures (not shown) such as a pad nitride layer and/or pad oxide layer atop of semiconductor substrate 100. It may further include one or more layers covering the sidewall and bottom of trench(es) 102. The following description references application of trench(es) 102 as trench capacitors. It is understood, however, trench(es) 102 may ultimately be used for a variety of semiconductor structures including, but not limited to: trench capacitors, shallow trench isolations (STI), contact vias and back-end-of-line (BEOL) damascene trench/via combinations.

In a next step S2, shown in FIGS. 2 and 3, each trench 102 is filled with a filling material 110. Filling material 110 is coated across semiconductor substrate 100. As filling material enters trench(es) 102, it creates a step height (SH) between trench area 104 and adjacent trench free areas 112. It has been discovered that trench volume is correlated to step height (SH), and by measuring step height (SH), the trench volume can be extrapolated. Furthermore, in terms of trench capacitors, since the trench capacitance is strongly dependent on trench surface area which is correlated to trench volume, trench capacitance can be further projected based on step height (SH).

In one embodiment, filling material 110 may include a resist or a dielectric. In the latter case, the dielectric may include, for example, spin-on-glass or SiLK®, the latter of which is available from Dow Chemical. If a resist is used, in one embodiment, the resist includes at least one solute and at least one solvent. For example, the resist may include an organic resin solute dissolved in a solvent such as propylene glycol monomethyl ether acetate (PGMEA) and 2-isopropanol or ethyl lactate. In this case, the filling step S2 may also include removing at least a portion of the solvent in filling material 110. In one embodiment, the removing step includes heating semiconductor substrate 100. For example, semiconductor substrate 100 may be heated to approximately 160-200° C. for approximately 30-180 seconds. As the at least portion of the solvent is removed, the volume of the resist is reduced. Use of a resist is advantageous relative to trench capacitors because resist is essential for subsequent formation of buried plates for trench capacitors. Therefore, there is no extra process step added up to this point. It is understood that the particular filling materials 110 described above are only illustrative and that other filling materials 110 may be used within the scope of the invention.

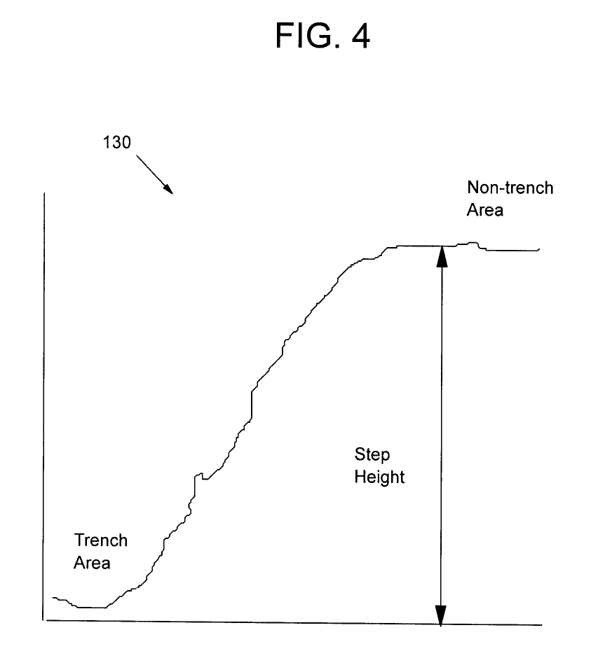

With continuing reference to FIGS. 2 and 3, a next step S3 includes measuring step height (SH) between trench area 104 and trench free area 112. This step may be carried out using a profilometer 120 such as an atomic force microscope (AFM). FIG. 4 shows a graphical user interface output from one embodiment of profilometer 120. As shown, profilometer 120 can discern and measure a height of the step very accurately. In the example shown, step height (SH) is approximately 0.62 μm, which is well within the resolution of an AFM.

The next step S4, as shown in FIG. 3, trench volume is determined based on step height (SH). As used herein, “trench volume” may be of a single trench or a combined volume where more than one trench is used. In one embodiment, the determining step includes establishing an empirical correlation between step height (SH) and trench volume. That is, data is collected for a number of step heights and corresponding trench volumes, and a correlation between step height (SH) and trench volume is established. The correlation can then be provided in any now known or later developed manner, e.g., an algorithm, lookup table, etc.

The above-described embodiments provide a simple, nondestructive, and reliable trench volume determination. In addition, the above-described embodiments can be provided as a fully automated in-line measurement and applied to all-wafers and to multiple-site measurement. Furthermore, the embodiments are more cost-effective because they can use conventional profilometers, such as an AFM, and require less turn-around time. The methods described above are also highly scalable because they measure a global step height (SH) of filling material 110 between trench area 104 and trench free area 112. As a result, the measurement capability is not limited by the size of each individual trench, and the technique can be used even as trenches are scaled to ever-smaller sizes.

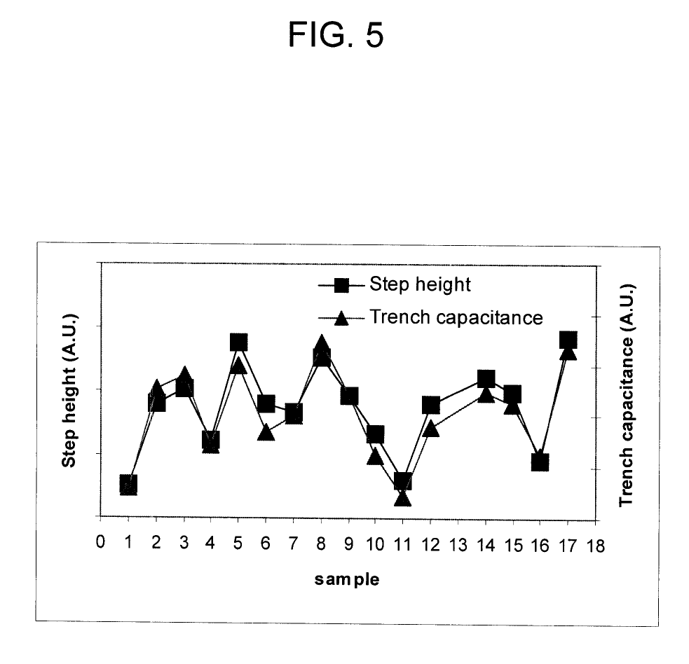

In an alternative embodiment, the above-described embodiments may also be employed to project a capacitance of trench(es) 102 in the case trench(es) 102 are used for a trench capacitor, as shown in FIG. 3 as step S5. The capacitance projection is based on the step height (SH). In particular, as known in the art, trench volume and/or trench surface area (the latter of which can be extracted based on the trench volume) can be correlated to trench capacitance. Similarly, a direct correlation between step height (SH) and trench capacitance can also be generated, e.g., based on empirical data. As a result, implementation of the above-described embodiments for determining a trench volume can also be used to project trench capacitance. Since step height (SH) can be measured at the very beginning of the trench capacitor fabrication process, this implementation enables an early projection of trench capacitance and therefore a quick feedback for process optimization. FIG. 5 shows a chart illustrating a correlation of step height (SH) and trench capacitance for a number of wafers using a resist filling material. In FIG. 5, the data points marked with a square indicate step height (SH), and the data points marked with a triangle indicate trench capacitance. As shown, the wafer-to-wafer variation of trench capacitance exactly follows the trend projected by step height (SH) measurement. The above-described implementation provides accuracy not otherwise available. It is understood that, if desired, step S4 can be omitted as part of the trench capacitance projecting embodiment.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

1. A method of determining trench volume, the method comprising:
providing a semiconductor substrate with at least one trench in a trench area;
filling each trench with a filling material;
measuring a step height between the trench area and a trench free area, wherein the step height represents a difference in thickness of the filling material on a top surface of the semiconductor substrate between the trench area and the trench free area; and
determining the trench volume based on the step height.

2. The method of claim 1, wherein the determining step includes collecting a plurality of step heights and corresponding trench volumes for establishing an empirical correlation between the step height and the trench volume, wherein the empirical correlation allows an unknown trench volume to be determined based on a known step height only.

3. The method of claim 1, wherein the filling material includes at least one solute and at least one solvent, and wherein the filling step includes coating the semiconductor substrate with the filling material and removing at least a portion of the solvent in the filling material.

4. The method of claim 3, wherein the removing step includes heating the semiconductor substrate.

5. The method of claim 1, wherein the measuring step includes using a profilometer to measure the step height.

6. The method of claim 1, wherein the filling material is selected from the group consisting of: a resist and a dielectric.

7. The method of claim 6, wherein the resist includes an organic resin dissolved in a solvent.

8. The method of claim 7, wherein the solvent includes propylene glycol monomethyl ether acetate (PGMEA) and one of 2-isopropanol and ethyl lactate.

9. The method of claim 1, further comprising the step of projecting a capacitance of the trench in the case the trench is used for a trench capacitor based on the trench volume.

10. A method of determining trench volume, the method comprising:
providing a semiconductor substrate with a plurality of trenches in a trench area;
coating the semiconductor substrate with a filling material that fills each trench, the filling material including at least one solute and at least one solvent;
removing at least a portion of the solvent in the filling material;
measuring a step height between the trench area and a trench free area, wherein the step height represents a difference in thickness of the filling material on a top surface of the semiconductor substrate between the trench area and the trench free area; and
determining the trench volume based on the step height only, the determination based on an empirical correlation between the step height and the trench volume.

11. The method of claim 10, wherein the measuring step includes using a profilometer to measure the step height.

12. The method of claim 10, wherein the removing step includes heating the semiconductor substrate.

13. The method of claim 10, wherein the filling material is selected from the group consisting of: a resist and a dielectric.

14. The method of claim 13, wherein the resist includes an organic resin dissolved in the at least one solvent.

15. The method of claim 14, wherein the at least one solvent includes propylene glycol monomethyl ether acetate (PGMEA) and one of 2-isopropanol and ethyl lactate.

16. The method of claim 10, further comprising the step of projecting a capacitance of the trench in the case the trench is used for a trench capacitor based on the trench volume.

17. A method of projecting a trench capacitance of a trench capacitor, the method comprising the steps of:
providing a semiconductor substrate with a plurality of trenches in a trench area;
coating the semiconductor substrate with a resist that fills each trench, the resist including at least one solute and at least one solvent;
removing at least a portion of the solvent in the resist by heating the semiconductor substrate;
measuring a step height between the trench area and a trench free area using a profilometer, wherein the step height represents a difference in thickness of the filling material on a top surface of the semiconductor substrate between the trench area and the trench free area; and
projecting the capacitance of the trench based on the step height only, the determination based on an empirical correlation between the step height and the trench capacitance.

18. The method of claim 17, wherein the profilometer includes an atomic force microscope.

19. The method of claim 17, wherein the at least one solute includes an organic resin dissolved in the at least one solvent, and wherein the at least one solvent includes propylene glycol monomethyl ether acetate (PGMEA) and one of 2-isopropanol and ethyl lactate.
